(19) United States
(12) Patent Application Publication
(10) Pub. No.: US 2022/0375780 A1
(43) Pub. Date: Nov. 24, 2022

(54) PROCESSING APPARATUS

(71) Applicant: DISCO CORPORATION, Tokyo (JP)

(72) Inventor: Atsunori AKAHANE, Tokyo (JP)

(21) Appl. No.: 17/660,667

(22) Filed: Apr. 26, 2022

(30) Foreign Application Priority Data
May 19, 2021 (JP) 2021-084762

(51) Int. Cl. H01L 21/683; H01L 21/67

(52) U.S. Cl. CPC H01L 21/6838; H01L 21/67092

(57) ABSTRACT

A holding unit of a processing apparatus includes a chuck table for holding the wafer thereon and a table base on which the chuck table is detachably supported. The chuck table includes a porous plate having an attracting surface for attracting the wafer thereto, a frame assembly surrounding a portion of the porous plate other than the attracting surface, a cooling water channel that is defined in the frame assembly and guides cooling water to an entire inner area of the frame assembly, a wafer suction hole that is defined in the frame assembly and transmits a suction force to the attracting surface of the porous plate, and a bolt hole defined in the frame assembly to fasten the chuck table to the table base.

### BACKGROUND OF THE INVENTION

### Field of the Invention

The present invention relates to a processing apparatus including at least a holding unit for holding a wafer under suction thereon, a processing unit having a rotatable grinding wheel for grinding the wafer held on the holding unit, and a processing fluid supply unit for supplying a processing fluid to the wafer.

### Description of the Related Art

Wafers with a plurality of devices such as integrated circuits (ICs) and large-scale integration (LSI) circuits formed in respective areas demarcated on their face side by a grid of projected dicing lines are ground on their reverse side to a desired thickness by a grinding apparatus, and then divided into individual device chips by a dicing apparatus, a laser processing apparatus, or the like. The device chips will be used in electronic appliances such as mobile phones and personal computers.

The grinding apparatus includes at least a holding unit for holding a wafer under suction thereon, a processing unit having a rotatable grinding wheel that includes an annular array of grindstones for grinding the wafer held on the holding unit, and a processing fluid supply unit for supplying a processing fluid to the wafer. The grinding apparatus is able to process, i.e., grind the wafer to a desired thickness (see, for example, JP 2005-153090A).

### SUMMARY OF THE INVENTION

JP 2005-153090A also discloses a processing apparatus for supplying a processing fluid of loose abrasive grains to the reverse side of a wafer and processing the reverse side of the wafer to a mirror finish with a polishing pad. The wafer is held under suction on a holding unit including a chuck table for holding the wafer thereon and a table base on which the chuck table is detachably supported. The chuck table includes a porous plate having a suction surface, i.e., a holding surface for attracting the wafer under suction, a frame surrounding portions of the porous plate other than the suction surface, a plurality of wafer suction holes that are defined in the bottom surface of the frame and transmit suction forces therethrough to the suction surface of the porous plate, and a plurality of bolt holes that are defined in the frame and receive therein respective bolts to fasten the chuck table to the table base. The chuck table is capable of holding the wafer thereon under suction forces applied through the wafer suction holes to the suction surface.

Before the processing apparatus processes the wafer, the processing unit of the grinding apparatus grinds the holding surface of the chuck table to make the holding surface identical in shape to a surface to be ground of the wafer to be placed and held on the chuck table. Then, when the processing apparatus processes the wafer, the thickness of the wafer is uniformized in its entirety.

However, it has been found that even though the holding surface of the chuck table is thus shaped and the wafer is processed, e.g., ground or polished, while being held on the shaped holding surface, the thickness of the processed wafer still has minute thickness variations ranging from approximately 2 μm to 3 μm, for example. Such minute thickness variations could lead to serious quality problems with very thin wafers that have recently been in growing demand in the art.

It is therefore an object of the present invention to provide a processing apparatus that is capable of restraining variations of the thickness of a processed wafer compared with the conventional processing apparatus.

In accordance with an aspect of the present invention, there is provided a processing apparatus including a holding unit for holding a wafer under suction thereon, a processing unit having a rotatable grinding wheel for grinding the wafer held on the holding unit, and a processing fluid supply unit for supplying a processing fluid to the wafer, in which the holding unit includes a chuck table for holding the wafer thereon, and a table base on which the chuck table is detachably supported, the chuck table includes a porous plate having an attracting surface for attracting the wafer thereto, a frame assembly surrounding a portion of the porous plate other than the attracting surface, a cooling water channel that is defined in the frame assembly and guides cooling water to an entire inner area of the frame assembly, a wafer suction hole that is defined in the frame assembly and transmits a suction force to the attracting surface of the porous plate, and a bolt hole defined in the frame assembly to fasten the chuck table to the table base, and the table base includes a rest surface on which a lower surface of the frame assembly is placed, a frame suction hole that is defined in the rest surface and transmits a suction force therethrough to attract the frame assembly to the rest surface, and a cooling water supply hole held in fluid communication with the cooling water channel for supplying cooling water to the cooling water channel.

Preferably, the wafer suction hole is defined in a plate rest surface of the frame assembly on which the porous plate is placed, and the rest surface of the table base has a fluid communication hole that is defined therein and held in fluid communication with the wafer suction hole and that transmits a suction force therethrough independently of the frame suction hole. Preferably, moreover, the wafer suction hole is defined in a side surface of the frame assembly, and the table base has a fluid communication hole that is defined in a side surface thereof and held in fluid communication with the wafer suction hole and that transmits a suction force therethrough independently of the frame suction hole.

The processing apparatus according to an aspect of the present invention includes at least the holding unit for holding the wafer under suction thereon, the processing unit having the rotatable grinding wheel for grinding the wafer held on the holding unit, and the processing fluid supply unit for supplying the processing fluid to the wafer. The holding unit includes the chuck table for holding the wafer thereon, and the table base on which the chuck table is detachably supported. The chuck table includes the porous plate having the attracting surface for attracting the wafer thereto, the frame assembly surrounding the portion of the porous plate other than the attracting surface, the cooling water channel that is defined in the frame assembly and guides cooling water to the entire inner area of the frame assembly, the wafer suction hole that is defined in the frame assembly and transmits the suction force to the attracting surface of the porous plate, and the bolt hole that is defined in the frame assembly and receives the bolt to fasten the chuck table to the table base. The table base includes the rest surface on which the lower surface of the frame assembly is placed, the frame suction hole that is defined in the rest surface and transmits the suction force therethrough to attract the frame assembly to the rest surface, and the cooling water supply hole that is held in fluid communication with the cooling water channel and supplies cooling water to the cooling water channel. Therefore, when either the attracting surface of the porous plate of the chuck table or the wafer is ground, the frame assembly in its entirety remains reliably fixed to the table base and is kept at a predetermined temperature by the cooling water throughout a grinding process carried out by the processing unit. Consequently, a holding surface of the chuck table, i.e., the attracting surface of the porous plate, and the ground surface of the wafer have their shapes essentially held in conformity with each other, restraining variations of the thickness of the wafer that has been ground.

The above and other objects, features and advantages of the present invention and the manner of realizing them will become more apparent, and the invention itself will best be understood from a study of the following description and appended claims with reference to the attached drawings showing preferred embodiments of the invention.

### BRIEF DESCRIPTION OF THE DRAWINGS

FIG. 1 is a perspective view of a grinding apparatus as a processing apparatus according to a first embodiment of the present invention;

FIG. 2A is a perspective view of a chuck table and a table base that make up a holding unit of the grinding apparatus illustrated in FIG. 1;

FIG. 2B is an exploded perspective view of the chuck table illustrated in FIG. 2A;

FIG. 3 is a plan view of a lower frame of the chuck table illustrated in FIGS. 2A and 2B;

FIG. 4A is a perspective view of the holding unit of the grinding apparatus illustrated in FIG. 1;

FIG. 4B is a cross-sectional view of the holding unit illustrated in FIG. 4A;

FIG. 5 is a perspective view illustrating the manner in which a suction surface of the holding unit is ground;

FIG. 6 is a perspective view illustrating the manner in which the reverse side of a wafer is ground by the grinding apparatus illustrated in FIG. 1;

FIG. 7A is a perspective view of a chuck table and a table base that make up a holding unit of a grinding apparatus according to a second embodiment of the present invention;

FIG. 7B is an exploded perspective view of the chuck table illustrated in FIG. 7A;

FIG. 8A is a perspective view of the holding unit illustrated in FIGS. 7A and 7B; and

FIG. 8B is a cross-sectional view of the holding unit illustrated in FIG. 8A.

### DETAILED DESCRIPTION OF THE PREFERRED EMBODIMENTS

The inventor of the present invention has conducted strenuous research focusing on possible causes of minute variations of the thicknesses of wafers that have been processed. As a consequence, the inventor has found that when a conventional grinding apparatus grinds a holding surface of a chuck table and when it grinds a wafer held under suction on the holding surface of the chuck table, a frame of the chuck table tends to be deformed into slightly different shapes, resulting in wafer thickness variations.

The inventor has come up with an idea that the above problem can be solved by keeping the frame of the chuck table from changing its shape as much as possible when the grinding apparatus grinds the holding surface of the chuck table and when it grinds the wafer held under suction on the holding surface of the chuck table. The processing apparatus according to preferred embodiments of the present invention will be described in detail hereinbelow with reference to the accompanying drawings.

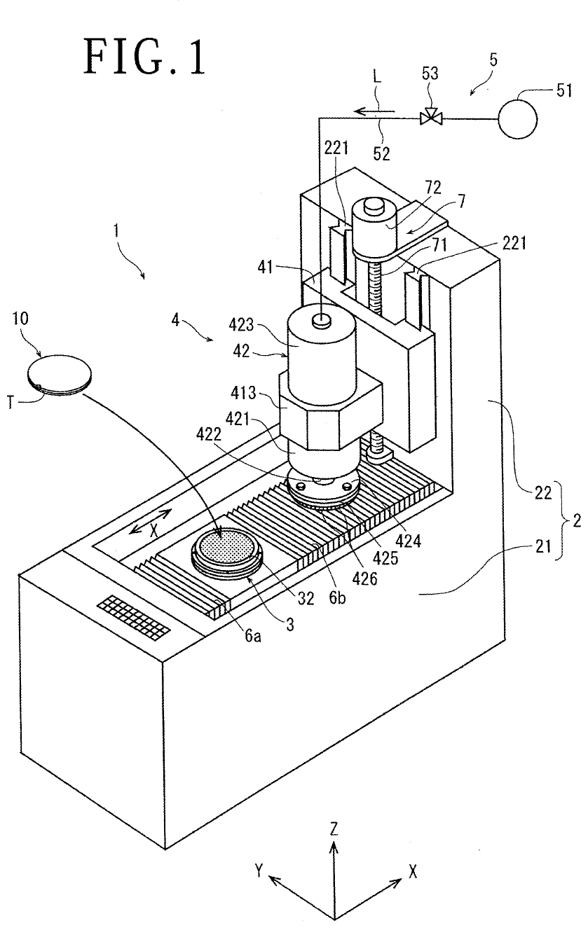

FIG. 1 illustrates, in perspective, a grinding apparatus 1 as a processing apparatus according to a first embodiment of the present invention. As illustrated in FIG. 1, the grinding apparatus 1 includes a holding unit 3 for holding under suction a plate-shaped wafer 10 as a workpiece to be processed according to the present embodiment, a grinding unit 4 as a processing unit for grinding the holding unit 3 and the wafer 10 held under suction on the holding unit 3, and a processing fluid supply unit 5 for supplying a processing fluid to the wafer 10. For illustrative purposes, a left end of the grinding apparatus 1 in FIG. 1 will be referred to as a front end and a right end thereof as a rear end.

The grinding apparatus 1 includes an apparatus housing 2. The apparatus housing 2 has a main body 21 shaped substantially as a rectangular parallelepiped and an upright wall 22 erected vertically from a rear end portion of the main body 21.

The holding unit 3 is disposed on the main body 21 and positioned between and joined to a pair of bellows-like covers 6a and 6b disposed on respective sides of the holding unit 3 in X-axis directions indicated by the arrow X. The holding unit 3 is movable in the X-axis directions by a moving mechanism, not illustrated, housed in the main body 21. When the moving mechanism is actuated, it moves the holding unit 3, while extending and contracting the covers 6a and 6b, in the X-axis directions between a loading/unloading region near the left end of the grinding apparatus 1 where an unprocessed wafer 10 is placed onto the holding unit 3 and a processing region near the rear end of the grinding apparatus 1 where the wafer 10 is processed directly below the grinding unit 4.

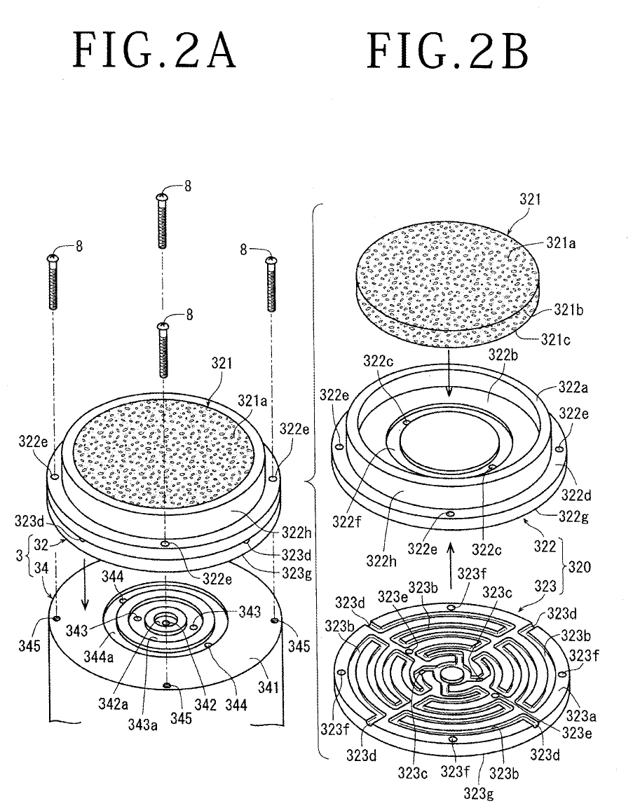

The holding unit 3 according to the present embodiment will be described in specific detail below with reference to FIGS. 2A and 2B. The holding unit 3 includes at least a circular chuck table 32 and a circular table base 34 on which the chuck table 32 is detachably supported. A rotary actuator, not illustrated, is connected to the table base 34 for rotating the table base 34 and the chuck table 32 about their central axis. As illustrated in FIG. 2B, the chuck table 32 includes a porous plate 321 having an attracting surface, i.e., a holding surface, 321a for attracting the wafer 10 under suction, and a frame assembly 320 surrounding portions of the porous plate 321 other than the attracting surface 321a, i.e., a side surface 321b and a reverse side 321c opposite the attracting surface 321a. The frame assembly 320 includes an upper frame 322 and a lower frame 323. The upper frame 322 includes an upper frame surface 322a, a side wall 322h extending downwardly from the upper frame surface 322a and providing a side surface, a plate rest surface 322b on which the reverse side 321c of the porous plate 321 is placed, a plurality of (according to the present embodiment, two) wafer suction holes 322c that is defined through the upper frame 322 between the plate rest surface 322b and a lower surface 322g of the upper frame 322 and that transmits a suction force, i.e., a negative pressure to the attracting surface 321a of the porous plate 321, an outer circumferential step 322d projecting radially outwardly from the side wall 322h and extending along the side wall 322h, and a plurality of bolt holes 322e that are defined through the outer circumferential step 322d and that receive therein respective bolts to fasten the frame assembly 320 to the table base 34. The wafer suction holes 322c that are open at the plate rest surface 322b are joined to each other by an annular groove 322f defined in and along the plate rest surface 322b. According to the present embodiment, the bolt holes 322e include four bolt holes (only three bolt holes illustrated in FIGS. 2A and 2B) angularly spaced at equal intervals along the outer circumferential step 322d. The lower surface 322g of the upper frame 322 lies flatwise except for areas where the wafer suction holes 322c are positioned.

The lower frame 323 has a face side 323a with a cooling water channel 323b defined therein as an upwardly open cavity having a predetermined depth. The lower frame 323 also has a plurality of (according to the present embodiment, two) cooling water supply holes 323c that are defined in a central area thereof, extend vertically therethrough, and supply cooling water from a cooling water supply source, not illustrated, to the cooling water channel 323b. The lower frame 323 further has a plurality of (according to the present embodiment, two) through holes 323e that are defined in areas of the face side 323a free of the cooling water channel 323b in alignment with the respective wafer suction holes 322c in the upper frame 322, extend vertically through the lower frame 323 and transmit the negative pressure to the wafer suction holes 322c. The lower frame 323 has four bolt holes 323f defined in an outer circumferential area thereof in alignment with the respective bolt holes 322e in the upper frame 322. The lower frame 323 has a lower surface 323g opposite the face side 323a, which lies flatwise except for areas where the cooling water supply holes 323c, the through holes 323e, etc. are positioned. When the upper frame 322 and the lower frame 323 are combined together into the frame assembly 320, the cooling water channel 323b has its upper open side closed by the lower surface 322g of the upper frame 322, providing a cooling water channel in the frame assembly 320. The cooling water channel has a plurality of (according to the present embodiment, four) cooling water drain ports 323d joined to outer circumferential ends thereof and open at an outer circumferential side surface of the lower frame 323. According to the present embodiment, the porous plate 321 is made of air-permeable porous ceramic, for example. According to the present invention, however, the porous plate may be made of any of other air-permeable materials that can be ground, e.g., a granular aggregate of pumice, resin, or metal, and should not be limited to any particular materials.

As illustrated in FIG. 2A, the table base 34 includes at least a rest surface 341 on which the frame assembly 320 is placed, a frame suction hole 342 defined in the rest surface 341 for transmitting a negative pressure from a suction source, not illustrated, therethrough to attract the lower surface 323g of the lower frame 323 of the frame assembly 320 to the rest surface 341, a plurality of (according to the present embodiment, two) cooling water supply holes 343 defined in the rest surface 341 for supplying cooling water to the respective cooling water supply holes 323c in the lower frame 323, and a plurality of (according to the present embodiment, two) first fluid communication holes 344 defined in the rest surface 341 in fluid communication with the wafer suction holes 322c in the upper frame 322 of the chuck table 32 and connected to a suction source, not illustrated, through suction passages independent of the frame suction hole 342. According to the present embodiment, the rest surface 341 has defined therein an increased-diameter recess 342a surrounding the frame suction hole 342, an annular groove 343a spaced radially outwardly from the increased-diameter recess 342a and interconnecting the cooling water supply holes 343, and an annular groove 344a spaced radially outwardly from the annular groove 343a and interconnecting the first fluid communication holes 344.

As illustrated in FIG. 2A, the frame suction hole 342 is defined in a central area of the rest surface 341 of the table base 34. The table base 34 also has four internally threaded bolt holes 345 defined in an outer circumferential edge portion of the rest surface 341 of the table base 34 in alignment with the respective bolt holes 322e in the upper frame 322 and the respective bolt holes 323f in the lower frame 323.

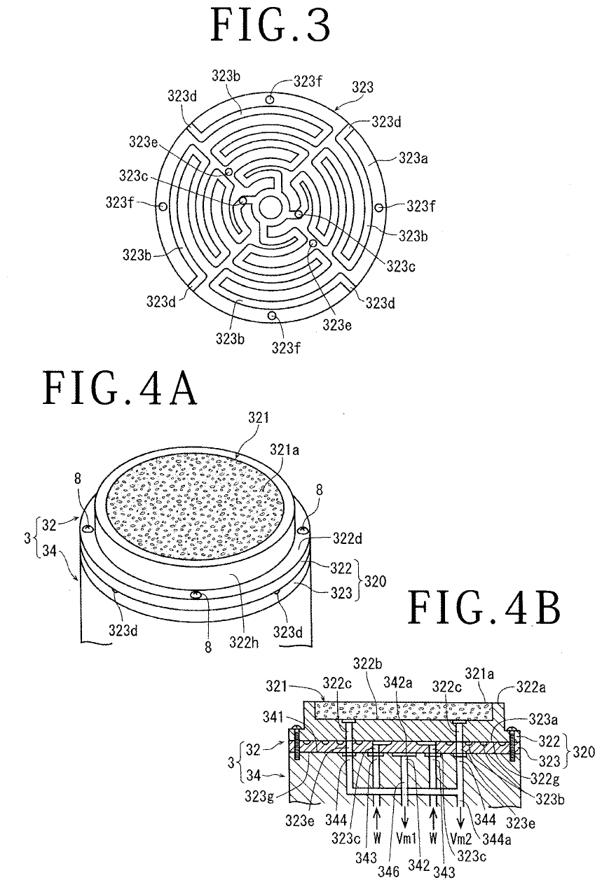

FIG. 3 illustrates the lower frame 323 in plan. As illustrated in FIG. 3, etc., the cooling water channel 323b is defined in the face side 323a of the lower frame 323 in its entirety. The cooling water channel 323b guides cooling water supplied through the cooling water supply holes 343 in the table base 34 and the cooling water supply holes 323c in the lower frame 323 to an entire inside area of the frame assembly 320, and drains the cooling water from the frame assembly 320 through the cooling water drain ports 323d. According to the present embodiment, the frame assembly 320 is illustrated as being made up of the upper frame 322 and the lower frame 323. According to the present invention, however, the frame assembly 320 is not limited to such details, but may be of an integral structure with a cooling water channel defined therein.

The chuck table 32 and the table base 34 are integrally fastened to each other by a plurality of bolts 8 inserted through the bolt holes 322e and 323f in the frame assembly 320 and threaded into the respective internally threaded bolt holes 345 in the table base 34.

FIG. 4A illustrates, in perspective, the holding unit 3 (see also FIGS. 2A and 2B) including the chuck table 32 placed on and fastened to the table base 34 by the bolts 8. FIG. 4B illustrates, in cross section, internal structural details of the holding unit 3 illustrated in FIG. 4A. In FIG. 4B, a plurality of passageways that are actually defined in the holding unit 3 on different cross-sectional planes are illustrated as though they are present on one cross-sectional plane for illustrative purposes.

As illustrated in FIG. 4B, the table base 34 has a first suction passageway 346 that is defined therein and transmits a suction force from a suction source, not illustrated, to the frame suction hole 342 defined in the rest surface 341 of the frame assembly 320. When no wafer 10 is held on the holding unit 3, the suction source connected to the first suction passageway 346 is actuated to apply a first suction force, i.e., a negative pressure, Vm1 through the first suction passageway 346, the frame suction hole 342, and the increased-diameter recess 342a to the lower surface 323g of the lower frame 323, attracting the lower frame 323 under suction. When the wafer 10 is placed on the attracting surface 321a of the porous plate 321, the suction source connected to the first fluid communication holes 344 is actuated to apply a second suction force, i.e., a negative pressure, Vm2 through the first fluid communication holes 344 in the table base 34, the through holes 323e in the lower frame 323, and the wafer suction holes 322c in the upper frame 322 to the attracting surface 321a of the porous plate 321, holding the wafer 10 under suction on the attracting surface 321a. The frame suction hole 342 and the first fluid communication holes 344 are connected to the respective suction sources, not illustrated, through the independent suction passages. Therefore, even when no wafer 10 is held on the holding unit 3, only the frame assembly 320 can be attracted to and held on the table base 34 under suction.

As illustrated in FIG. 1, the grinding unit 4 is disposed on a front surface of the upright wall 22. The grinding unit 4 includes a movable base 41 and a spindle unit 42 fixedly mounted on the movable base 41. The movable base 41 has a rear surface slidably engaging a pair of guide rails 221 vertically disposed on the front surface of the upright wall 22, so that the movable base 41 is vertically movable in Z-axis directions along the guide rails 221.

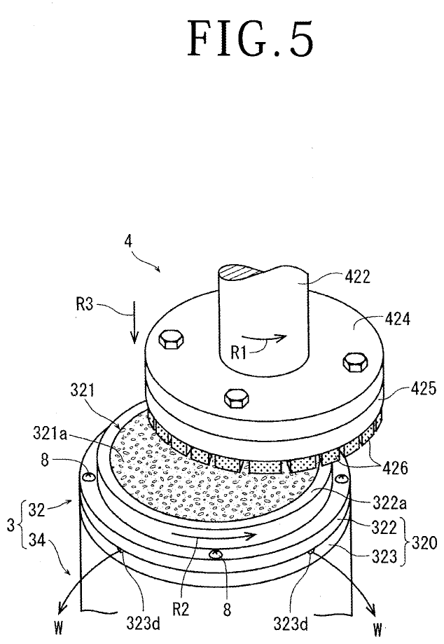

The spindle unit 42 includes a spindle housing 421 supported on a support 413 integral with the movable base 41, a spindle 422 rotatably held in the spindle housing 421, and a servomotor 423 coupled to the spindle 422 as rotating means for rotating the spindle 422 about its central axis. The spindle 422 has a lower end portion projecting downwardly from a lower end of the spindle housing 421 and having a lower end connected to a mounter 424. The grinding unit 4 also includes a grinding wheel 425 mounted on a lower surface of the mounter 424 and an annular array of grindstones 426 disposed on a lower surface of the grinding wheel 425 (see also FIG. 5).

As illustrated in FIG. 1, the grinding apparatus 1 includes a grinding feed mechanism 7 for moving the grinding unit 4 vertically in directions perpendicular to a holding surface, i.e., the attracting surface 321a of the chuck table 32 along the guide rails 221. The grinding feed mechanism 7 includes an externally threaded rod 71 disposed over the front surface of the upright wall 22 and extending vertically. The externally threaded rod 71 has upper and lower ends rotatably supported on the upright wall 22. A stepping motor 72 as a rotary actuator for rotating the externally threaded rod 71 about its central axis has an output shaft connected to the upper end of the externally threaded rod 71. The externally threaded rod 71 is operatively threaded through an internally threaded hole defined in a threaded joint, i.e., a nut, not illustrated, on a rear surface of the movable base 41. When the stepping motor 72 is energized to rotate its output shaft in one direction, the grinding feed mechanism 7 lowers the movable base 41 and hence the grinding unit 4 along the guide rails 221. When the stepping motor 72 is reversed to rotate its output shaft in the opposite direction, the grinding feed mechanism 7 lifts the movable base 41 and hence the grinding unit 4 along the guide rails 221.

As described above, the grinding apparatus 1 includes the processing fluid supply unit 5 for supplying a processing fluid, such as a grinding fluid, to the wafer 10 that is being ground on the holding unit 3. The processing fluid supply unit 5 includes a processing fluid tank 51 for storing a processing fluid L, i.e., grinding water, therein, the processing fluid tank 51 having a pressure feed pump for delivering the processing fluid L from the processing fluid tank 51, a processing fluid supply passageway 52 interconnecting the processing fluid tank 51 and the grinding unit 4, and an on/off valve 53 for selectively opening and closing the processing fluid supply passageway 52. When the pressure feed pump of the processing fluid tank 51 is actuated and the on/off valve 53 is opened, the processing fluid L is supplied from the processing fluid tank 51 through the processing fluid supply passageway 52 and the grinding unit 4 to the processing region.

The grinding apparatus 1 according to the present embodiment is basically constructed as described above. Functions and operation of the grinding apparatus 1 will be described below.

In preparation for grinding the wafer 10 on the grinding apparatus 1, as described above, the grinding unit 4 grinds the holding surface of the chuck table 32, i.e., the attracting surface 321a of the porous plate 321, as illustrated in FIG. 5, before grinding the wafer 10. For carrying out the grinding process, as described above with reference to FIG. 4B, the suction source connected to the first suction passageway 346 is actuated to apply the first suction force Vm1 to the lower surface 323g of the lower frame 323, attracting the frame assembly 320 under suction to the table base 34. At this time, since no wafer 10 is placed on the attracting surface 321a of the chuck table 32, it is not necessary to transmit the second suction force Vm2 through the first fluid communication holes 344 in the table base 34 and the wafer suction holes 322c and the through holes 323e in the frame assembly 320 to the attracting surface 321a of the porous plate 321.

Then, the moving mechanism, not illustrated, is actuated to move and position the chuck table 32 in the processing region below the grinding unit 4, i.e., a position where the grindstones 426 of the grinding unit 4 will move across the central axis of the chuck table 32, as illustrated in FIG. 5. Thereafter, the servomotor 423 is energized to rotate the spindle 422 of the grinding unit 4 about its central axis at a predetermined rotational speed of 4000 rpm, for example, in the direction indicated by the arrow R1 in FIG. 5, and the rotary actuator connected to the table base 34 is actuated to rotate the chuck table 32 about its central axis at a predetermined rotational speed of 300 rpm, for example, in the direction indicated by the arrow R2. At this time, the cooling water supply source is actuated to supply cooling water W through the cooling water supply holes 343 in the table base 34 to the cooling water channel 323b in the frame assembly 320.

Then, the grinding feed mechanism 7 is actuated to lower the grinding unit 4 in the direction indicated by the arrow R3, bringing the grindstones 426 on the lower surface of the grinding wheel 425 into abrasive contact with the porous plate 321 of the chuck table 32 to grind the attracting surface 321a of the porous plate 321. The grinding unit 4 is continuously lowered in the direction indicated by the arrow R3 at a rate of 0.1 μm/second, for example, while the processing fluid L is being supplied from the processing fluid supply unit 5 to the attracting surface 321a of the porous plate 321, thereby grinding the attracting surface 321a. While the attracting surface 321a is being ground, the cooling water supply source is continuously actuated to cause the cooling water W to flow through the cooling water channel 323b in the frame assembly 320 and drain from the cooling water drain ports 323d, cooling the frame assembly 320 to a predetermined temperature. When the attracting surface 321a of the porous plate 321 and the upper frame surface 322a of the upper frame 322 have been ground for a predetermined period of time or to a predetermined depth, the grinding feed mechanism 7 is turned off, and then the grinding process comes to an end after the grinding apparatus 1 has operated idly for a predetermined period of time. While the processing fluid L is being supplied from the processing fluid supply unit 5 to the holding surface of the chuck table 32, the processing fluid L may also be supplied through the wafer suction holes 322c to the attracting surface 321a of the porous plate 321 such that the processing fluid L can be ejected from the attracting surface 321a, as the second suction force Vm2 is not transmitted through the wafer suction holes 322c at this time.

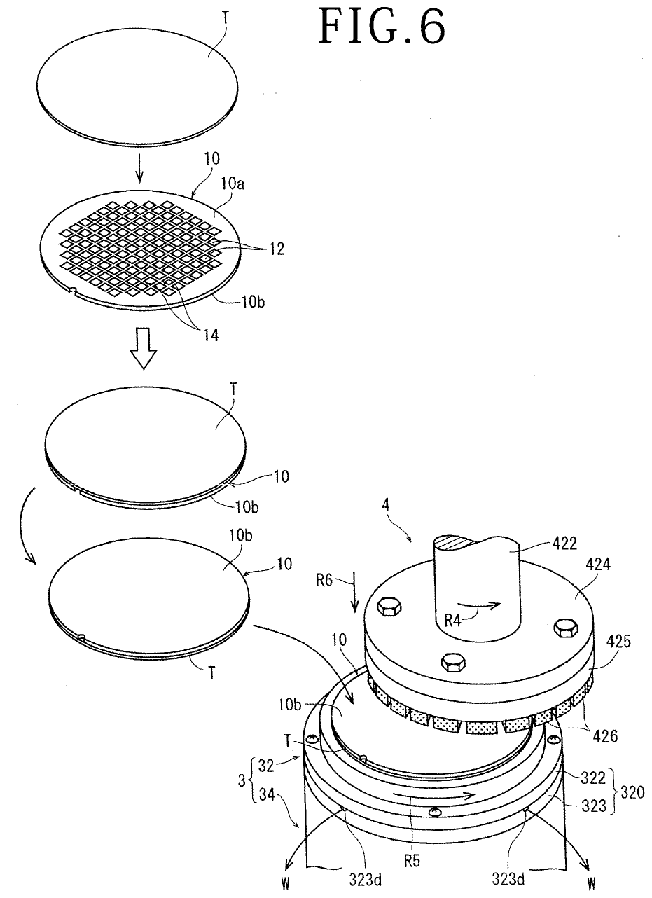

After the attracting surface 321a of the porous plate 321 has been ground, a grinding process is performed on the wafer 10 as illustrated in FIG. 6. The attracting surface 321a of the porous plate 321 is not ground each time a wafer 10 is to be ground, but is ground once a day, for example. As illustrated in a left section of FIG. 6, the wafer 10 has a plurality of devices 12 formed in respective areas demarcated on a face side 10a thereof by a grid of projected dicing lines 14. A protective tape T is integrally affixed to the face side 10a of the wafer 10. Then, the wafer 10 is reversed, i.e., turned upside down with a reverse side 10b thereof facing upwardly and the protective tape T facing downwardly, and then placed on the chuck table 32 that has been moved to and positioned in the loading/unloading region.

For performing the grinding process on the reverse side 10b of the wafer 10, as described above with reference to FIG. 4B, the suction source connected to the first suction passageway 346 is actuated to apply the first suction force Vm1 to the lower surface 323g of the lower frame 323, attracting the frame assembly 320 under suction to the table base 34. Moreover, the suction source connected to the first fluid communication holes 344 is actuated to apply the second suction force Vm2 through the first fluid communication holes 344 in the table base 34, the through holes 323e in the lower frame 323, and the wafer suction holes 322c in the upper frame 322 to the attracting surface 321a of the porous plate 321, holding the wafer 10 under suction on the attracting surface 321a.

Then, the moving mechanism, not illustrated, is actuated to move and position the chuck table 32 in the processing region below the grinding unit 4, i.e., a position where the grindstones 426 of the grinding unit 4 will move across the central axis of the chuck table 32 on which the wafer 10 is held under suction. Thereafter, the servomotor 423 is energized to rotate the spindle 422 of the grinding unit 4 about its central axis at a predetermined rotational speed of 4000 rpm, for example, in the direction indicated by the arrow R4 in FIG. 6, and the rotary actuator connected to the table base 34 is actuated to rotate the chuck table 32 about its central axis at a predetermined rotational speed of 300 rpm, for example, in the direction indicated by the arrow R5. At this time, the cooling water supply source is actuated to supply cooling water W through the cooling water supply holes 343 in the table base 34 to the cooling water channel 323b in the frame assembly 320. Then, while the processing fluid L is being supplied from the processing fluid supply unit 5 to the reverse side 10b of the wafer 10, the grinding feed mechanism 7 is actuated to lower the grinding unit 4 in the direction indicated by the arrow R6 at a rate of 0.1 μm/second, for example, bringing the grindstones 426 into abrasive contact with the reverse side 10b of the wafer 10. In this manner, the grindstones 426 grind the reverse side 10b of the wafer 10 while the thickness of the wafer 10 is being detected by thickness detecting means, not illustrated. During the grinding process, the cooling water supply source is continuously actuated to cause the cooling water W to flow through the cooling water channel 323b in the frame assembly 320 and drain from the cooling water drain ports 323d, cooling the frame assembly 320 to a predetermined temperature. When the reverse side 10b of the wafer 10 has been ground, the grinding feed mechanism 7 is turned off, bringing the grinding process to an end.

According to the first embodiment described above, when either the attracting surface 321a of the porous plate 321 of the chuck table 32 or the reverse side 10b of the wafer 10 is ground, the frame assembly 320 in its entirety remains reliably fixed to the table base 34 and is kept at a predetermined temperature by the cooling water W throughout the grinding process carried out by the grinding wheel 425 of the grinding unit 4. Consequently, the holding surface of the chuck table 32 and the ground surface of the wafer 10 have their shapes essentially held in conformity with each other, restraining variations of the thickness of the wafer 10 that has been ground.

According to the above embodiment, furthermore, since the wafer suction holes 322c for transmitting a suction force to the attracting surface 321a of the porous plate 321 that acts as the holding surface of the chuck table 32 and the frame suction hole 342 for attracting the frame assembly 320 of the chuck table 32 to the rest surface 341 of the table base 34 are provided independently of each other, the processing fluid L mixed with ground-off chips drawn through the porous plate 321 is prevented from finding its way between the rest surface 341 and the frame assembly 320, and hence thickness variations of the wafer 10 caused by such ground-off chips are restrained.

Moreover, after the reverse side 10b of the wafer 10 has been ground, a mixture of air and water is supplied through the wafer suction holes 322c to the porous plate 321 and ejected therefrom. When the wafer 10 is released and unloaded from the chuck table 32, the processing fluid L mixed with the ground-off chips that have entered the wafer suction holes 322c is also ejected from the porous plate 321. As the wafer suction holes 322c and the frame suction hole 342 are independent of each other, the processing fluid L mixed with the ground-off chips is prevented from finding its way between the rest surface 341 and the frame assembly 320, and hence thickness variations of the wafer 10 caused by such ground-off chips are restrained, as described above. Even if the processing apparatus is an apparatus for polishing a wafer using loose abrasive gains, the loose abrasive grains are preventing from reaching the rest surface 341 of the table base 34, and hence thickness variations of the wafer 10 caused by such loose abrasive grains are restrained. As the cooling water channel 323b is defined in the frame assembly 320, the cooling water W flowing through the cooling water channel 323b keeps the chuck table 32 at a predetermined temperature, thereby restraining thermal expansion of the frame assembly 320 and hence thickness variations of the wafer 10.

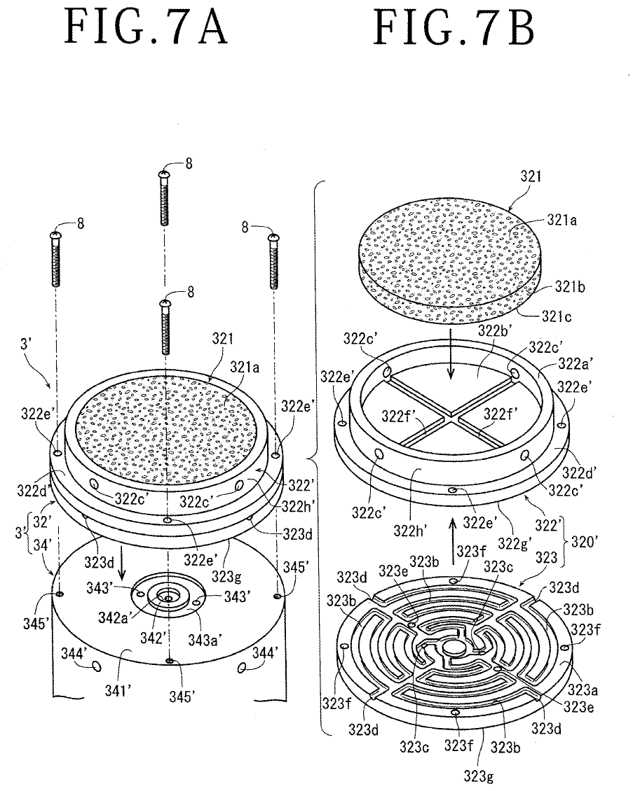

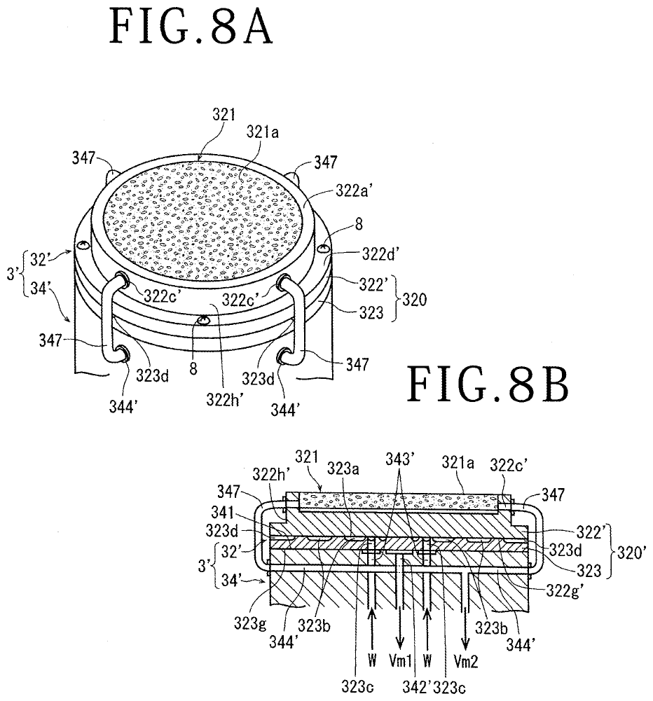

The present invention is not limited to the processing apparatus according to the first embodiment described above, but may be applied to a grinding apparatus according to a second embodiment to be described below. The grinding apparatus according to the second embodiment will be described below with reference to FIGS. 7A, 7B, 8A, and 8B. The grinding apparatus according to the second embodiment is different from the grinding apparatus 1 according to the first embodiment as to only a holding unit 3′. Therefore, the other structural details of the grinding apparatus according to the second embodiment will not be described below, and those parts of the holding unit 3′ that are identical to those of the holding unit 3 according to the first embodiment are denoted by identical reference characters and will be omitted from description.

As illustrated in FIGS. 7A and 7B, the holding unit 3′ includes at least a circular chuck table 32′ and a circular table base 34′ on which the chuck table 32′ is detachably supported. As illustrated in FIG. 7B, the chuck table 32′ includes a porous plate 321 having an attracting surface, i.e., a holding surface, 321a for attracting the wafer 10 under suction, and a frame assembly 320′ surrounding portions of the porous plate 321 other than the attracting surface 321a, i.e., a side surface 321b and a reverse side 321c opposite the attracting surface 321a. The frame assembly 320′ includes an upper frame 322′ and a lower frame 323. The lower frame 323 is structurally identical to the lower frame 323 according to the first embodiment. The upper frame 322′ includes a side wall 322h′ having an upper frame surface 322a′ and providing a side surface, a plurality of (according to the present embodiment, four) wafer suction holes 322c′ that are defined through the side wall 322h′ and transmit a suction force, i.e., a negative pressure to the attracting surface 321a of the porous plate 321, an outer circumferential step 322d′ projecting radially outwardly from the side wall 322h′ and extending along the side wall 322h′, and a plurality of bolt holes 322e′ that are defined through the outer circumferential step 322d′ and that receive therein respective bolts to fasten the frame assembly 320′ to the table base 34′.

The upper frame 322′ has a plate rest surface 322b′ on which the reverse side 321c of the porous plate 321 is placed, the plate rest surface 322b′ having two straight grooves 322f′ joining the four wafer suction holes 322c′ defined in the side wall 322h′ and intersecting with each other. The upper frame 322′ has a flat lower surface 322g′.

As illustrated in FIG. 7A, the table base 34′ includes at least a rest surface 341′ on which a lower surface 323g of the frame assembly 320′ opposite to the plate rest surface 322b′ is placed, a frame suction hole 342′ that is defined in the rest surface 341′ and transmits a negative pressure from a suction source, not illustrated, to attract the lower surface 323g of the lower frame 323 of the frame assembly 320′, a plurality of (according to the present embodiment, two) cooling water supply holes 343′ that are defined in the rest surface 341′ and supply cooling water to the respective cooling water supply holes 323c in the lower frame 323 illustrated in FIG. 7B, and a plurality of (according to the present embodiment, four) second fluid communication holes 344′ held in fluid communication with the wafer suction holes 322c′ defined in the upper frame 322′ and connected to a suction source, not illustrated, through suction passages independent of the frame suction hole 342′. According to the present embodiment, the rest surface 341′ has defined therein an increased-diameter recess 342a′ surrounding the frame suction hole 342′ and an annular groove 343a′ spaced radially outwardly from the increased-diameter recess 342a′ and interconnecting the cooling water supply holes 343′.

The frame suction hole 342′ is defined in a central area of the rest surface 341′ of the table base 34′. The table base 34′ also has four internally threaded bolt holes 345′ defined in an outer circumferential edge portion of the rest surface 341′ of the table base 34′ in alignment with the respective bolt holes 322e′ in the upper frame 322′ and the respective bolt holes 323f in the lower frame 323. As illustrated in FIG. 8A as well as FIGS. 7A and 7B, the chuck table 32′ and the table base 34′ are integrally fastened to each other by a plurality of bolts 8 inserted through the bolt holes 322e′ in the frame assembly 320′ and threaded into the respective internally threaded bolt holes 345′ in the table base 34′. The wafer suction holes 322c′ and the second fluid communication holes 344′ are held in fluid communication with each other by fluid communication passages 347.

FIG. 8B illustrates the holding unit 3′ in cross section. The second fluid communication holes 344′ are connected to a suction source, not illustrated, through passages independent of the frame suction hole 342′. In FIG. 8B, a plurality of passageways that are actually defined in the holding unit 3′ on cross-sectional planes different from those in FIG. 4B are illustrated as though they are present on one cross-sectional plane for the purpose of illustrating connections of the fluid communication passages 347.

With the holding unit 3′ according to the second embodiment illustrated in FIGS. 7A, 7B, 8A, and 8B, the table base 34′ includes the frame suction hole 342′ defined in the rest surface 341′ on which the lower surface 323g of the frame assembly 320′ is placed. When the suction source connected to the frame suction hole 342′ is actuated, the suction source applies a first suction force, i.e., a negative pressure, Vm1 through the frame suction hole 342′ to the lower surface 323g of the frame assembly 320′, attracting the frame assembly 320′ under suction to the table base 34′. When the wafer 10 is placed on the attracting surface 321a of the porous plate 321, the suction source connected to the second fluid communication holes 344′ is actuated to apply a second suction force, i.e., a negative pressure, Vm2 through the second fluid communication holes 344′ in the table base 34′, the fluid communication passages 347, and the wafer suction holes 322c′ to the attracting surface 321a of the porous plate 321, holding the wafer 10 under suction on the attracting surface 321a. The cooling water supply source, not illustrated, is actuated to supply cooling water W through the cooling water supply holes 343′ in the table base 34′ to the cooling water channel 323b in the frame assembly 320′.

According to the second embodiment illustrated in FIGS. 7A, 7B, 8A, and 8B, the frame suction hole 342′ and the second fluid communication holes 344′ are connected to the respective suction sources, not illustrated, through the independent suction passages. Moreover, the cooling water channel 323b is defined in the frame assembly 320′. Therefore, the holding unit 3′ according to the second embodiment offers the same advantages as those of the holding unit 3 according to the first embodiment described with reference to FIGS. 2A, 2B, 3, 4A, and 4B. According to the second embodiment, furthermore, the second suction force Vm2 transmitted to the attracting surface 321a of the porous plate 321 held by the upper frame 322′ is supplied through the wafer suction holes 322c′ defined in the side wall 322h′ of the upper frame 322′, the fluid communication passages 347, and the second fluid communication holes 344′, but not through the rest surface 341′ of the table base 34′. Consequently, the processing fluid L mixed with ground-off chips is reliably prevented from entering between the rest surface 341′ of the table base 34′ and the frame assembly 320′, and hence thickness variations of the wafer 10 caused by such ground-off chips are restrained.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A processing apparatus comprising:
a holding unit for holding a wafer under suction thereon;
a processing unit having a rotatable grinding wheel for grinding the wafer held on the holding unit; and
a processing fluid supply unit for supplying a processing fluid to the wafer, wherein
the holding unit includes
a chuck table for holding the wafer thereon, and
a table base on which the chuck table is detachably supported,
the chuck table includes
a porous plate having an attracting surface for attracting the wafer thereto,
a frame assembly surrounding a portion of the porous plate other than the attracting surface,
a cooling water channel that is defined in the frame assembly and guides cooling water to an entire inner area of the frame assembly,
a wafer suction hole that is defined in the frame assembly and transmits a suction force to the attracting surface of the porous plate, and
a bolt hole defined in the frame assembly to fasten the chuck table to the table base, and
the table base includes
a rest surface on which a lower surface of the frame assembly is placed,
a frame suction hole that is defined in the rest surface and transmits a suction force therethrough to attract the frame assembly to the rest surface, and
a cooling water supply hole held in fluid communication with the cooling water channel for supplying cooling water to the cooling water channel.

2. The processing apparatus according to claim 1, wherein
the wafer suction hole is defined in a plate rest surface of the frame assembly on which the porous plate is placed, and
the rest surface of the table base has a fluid communication hole that is defined therein and held in fluid communication with the wafer suction hole and that transmits a suction force therethrough independently of the frame suction hole.

3. The processing apparatus according to claim 1, wherein
the wafer suction hole is defined in a side surface of the frame assembly, and
the table base has a fluid communication hole that is defined in a side surface thereof and held in fluid communication with the wafer suction hole and that transmits a suction force therethrough independently of the frame suction hole.
